(19) United States
(12) Patent Application Publication
(10) Pub. No.: US 2024/0404854 A1
(43) Pub. Date: Dec. 5, 2024

(54) SUBSTRATE PROCESSING APPARATUS AND SUBSTRATE PROCESSING METHOD USING THE SAME

(71) Applicant: SAMSUNG ELECTRONICS CO., LTD., Suwon-si (KR)

(72) Inventors: Jaeho Jung, Suwon-si (KR); Yuyeon Kim, Suwon-si (KR); Siyeong Yang, Suwon-si (KR)

(21) Appl. No.: 18/633,117

(22) Filed: Apr. 11, 2024

(30) Foreign Application Priority Data
Jun. 1, 2023 (KR) 10-2023-0071149
Aug. 28, 2023 (KR) 10-2023-0112955

(51) Int. Cl. H01L 21/673; H01L 21/67

(52) U.S. Cl. CPC H01L 21/67313; H01L 21/67023; H01L 21/67098

(57) ABSTRACT

The present disclosure relates to substrate processing apparatuses and substrate processing methods. An example substrate processing apparatus comprises an outer chamber that provides an internal space, a process tube in the outer chamber, a heater between the outer chamber and the process tube, and a boat inserted into the process tube. The boat includes a plurality of substrate support devices that are vertically stacked. Each substrate support device of the plurality of substrate support devices includes a support member that supports a substrate, a lower electrode below the support member, and an upper electrode above the support member and spaced apart from the support member.

### CROSS-REFERENCE TO RELATED APPLICATIONS

This application claims priority under 35 U.S.C § 119 to Korean Patent Applications No. 10-2023-0071149 filed on Jun. 1, 2023, and No. 10-2023-0112955 filed on Aug. 28, 2023, in the Korean Intellectual Property Office, the disclosures of which are hereby incorporated by reference in their entirety.

### BACKGROUND

A semiconductor device may be fabricated by using various processes. For example, a semiconductor device may be fabricated through a photolithography process, an etching process, a deposition process, and an annealing process that are performed on a silicon wafer. In the annealing process, a substrate may be provided with heat. A substrate processing apparatus may be used to provide the substrate with heat.

### SUMMARY

The present disclosure relates to substrate processing apparatuses, including a substrate processing apparatus capable of applying a vertical directional electric field, a substrate processing apparatus capable of uniformly heating a substrate, and a substrate processing apparatus capable of increasing a yield, and substrate processing methods using the same.

The object of the present disclosure is not limited to the mentioned above, and other objects which have not been mentioned above will be clearly understood to those skilled in the art from the following description.

In some implementations, a substrate processing apparatus comprises: an outer chamber that provides an internal space; a process tube in the outer chamber; a heater between the outer chamber and the process tube; and a boat inserted into the process tube. The boat includes a plurality of substrate support devices that are vertically stacked. Each of the plurality of substrate support devices includes: a support member that supports a substrate; a lower electrode below the support member; and an upper electrode upwardly spaced apart from the support member.

In some implementations, a substrate processing apparatus comprises: a process chamber; a support member in the process chamber and supporting a substrate; a lower electrode below the support member; an upper electrode upwardly spaced apart from the support member; and a heater in the process chamber. The heater is disposed to horizontally surround a process space between the support member and the upper electrode.

In some implementations, a substrate processing method comprises: placing a substrate in a substrate processing apparatus; and processing the substrate disposed in the substrate processing apparatus. The substrate processing apparatus includes: a support member that supports the substrate; a lower electrode below the support member; an upper electrode upwardly spaced apart from the support member; and a heater that horizontally surrounds a space between the support member and the upper electrode. The step of processing the substrate includes: using the heater to heat the substrate on the support member; and applying a power to at least one selected from the lower electrode and the upper electrode.

Details of other example implementations are included in the description and drawings.

### BRIEF DESCRIPTION OF THE DRAWINGS

FIG. 1 illustrates a cross-sectional view showing an example of a substrate processing apparatus.

FIG. 2 illustrates an example enlarged cross-sectional view showing section X of FIG. 1.

FIG. 3 illustrates an example enlarged cross-sectional view showing section Y of FIG. 1.

FIG. 4 illustrates an example enlarged cross-sectional view showing section Z of FIG. 3.

FIG. 5 illustrates an exploded perspective view showing an example of a substrate processing apparatus.

FIG. 6 illustrates a cutoff perspective view showing an example of a substrate processing apparatus.

FIG. 7 illustrates a flow chart showing an example of a substrate processing method.

FIGS. 8 to 13 illustrate example cross-sectional views showing a substrate processing method according to the flow chart of FIG. 7.

FIG. 14 illustrates a cross-sectional view showing another example of a substrate processing apparatus.

FIG. 15 illustrates a cross-sectional view showing a use state of an example of a substrate processing apparatus.

### DETAILED DESCRIPTION

The following will now describe some implementations of the present disclosure with reference to the accompanying drawings. Like reference numerals may indicate like components throughout the description.

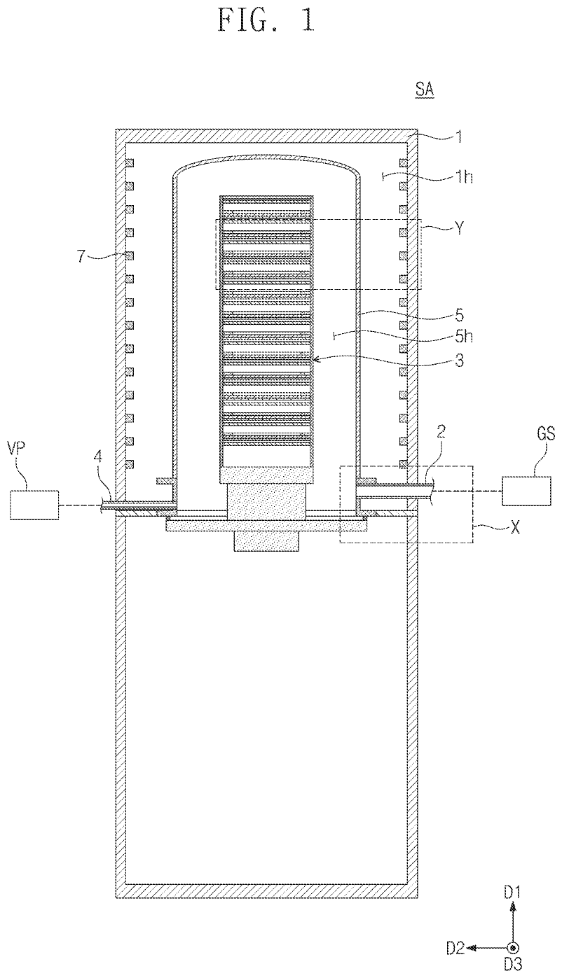

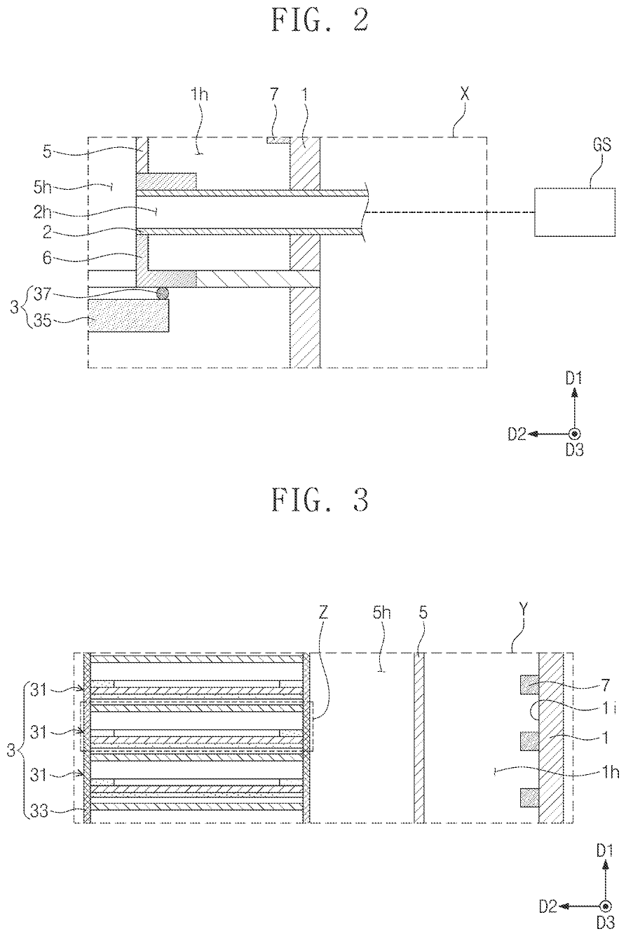

FIG. 1 illustrates a cross-sectional view showing an example of a substrate processing apparatus. FIG. 2 illustrates an example enlarged cross-sectional view showing section X of FIG. 1.

In this description, symbol D1 may indicate a first direction, symbol D2 may indicate a second direction that intersects the first direction D1, and symbol D3 may indicate a third direction that intersects each of the first direction D1 and the second direction D2. The first direction D1 may be called a vertical direction. Each of the second direction D2 and the third direction D3 may be called a horizontal direction.

Referring to FIGS. 1 and 2, a substrate processing apparatus SA may be provided. The substrate processing apparatus SA may perform a process on a substrate. The substrate processing apparatus SA may heat a substrate. For example, the substrate processing apparatus SA may be configured such that a substrate is heated to force a material present on a surface of the substrate to diffuse into the substrate. In this sense, an annealing process may be performed in the substrate processing apparatus SA. The substrate processing apparatus SA may include an outer chamber 1, a process tube 5, a boat 3, a heater 7, a tube support member 6, a gas nozzle 2, an exhaust line 4, a pump VP, and a gas supply GS.

The outer chamber 1 may provide an internal space 1h. The outer chamber 1 may have a hollow cylindrical shape, but the present disclosure are not limited thereto. The outer chamber 1 may separate the internal space 1h from an external space. The outer chamber 1 may include a rigid material. The outer chamber 1 may include quartz, but the present disclosure are not limited thereto.

The process tube 5 may be positioned in the outer chamber 1. For example, the process tube 5 may be placed in the internal space 1h. The process tube 5 may provide a tube space 5h. The tube space 5h may extend in the first direction D1. The tube space 5h may have a circular shape when viewed in plan. For example, the process tube 5 may have a hollow cylindrical shape. The tube space 5h may be connected through the gas nozzle 2 to the gas supply GS. The tube space 5h may be connected through the exhaust line 4 to the pump VP. The process tube 5 may include a rigid material. The process tube 5 may include quartz, but the present disclosure are not limited thereto.

The boat 3 may be inserted into the process tube 5. The boat 3 may be selectively disposed in the tube space 5h. For example, the boat 3 may be movable in the first direction D1 to be inserted into the process tube 5. The boat 3 may support a substrate. The boat 3 may create an electric field on a substrate disposed in the boat 3. The boat 3 will be further discussed in detail below.

The heater 7 may heat a fluid in the internal space 1h and/or the tube space 5h. The heater 7 may heat a substrate in the boat 3. Thus, a substrate may increase in temperature. The heater 7 may be, for example, positioned between the outer chamber 1 and the process tube 5. The present disclosure, however, are not limited thereto, and the heater 7 may be positioned outside the outer chamber 1. Alternatively, the heater 7 may be positioned inside the process tube 5. The heater 7 may include, for example, a coil. The heater 7 will be further discussed in detail below.

The tube support member 6 may support the process tube 5. Below the process tube 5, the tube support member 6 may support the process tube 5. The tube support member 6 may cause the process tube 5 to reside on a fixed position in the outer chamber 1.

The gas nozzle 2 may supply the internal space 1h with a gas. For example, a gas may be supplied through a supply path 2h of the gas nozzle 2 to the tube space 5h that is a portion of the internal space 1h. The gas nozzle 2 may supply the tube space 5h with a gas provided from the gas supply GS. The gas nozzle 2 may be positioned in the process tube 5 to allow a gas to be upwardly supplied in the tube space 5h. The gas nozzle 2 may penetrate the tube support member 6. For example, the gas nozzle 2 may horizontally penetrate the tube support member 6 to come into connection with the tube space 5h. The present disclosure, however, are not limited thereto, and the gas nozzle 2 may be provided at a position to allow the supply path 2h to connect with the tube space 5h.

The exhaust line 4 may exhaust a gas from the tube space 5h. For example, the pump VP may discharge a gas through the exhaust line 4 from the tube space 5h. The exhaust line 4 may penetrate the tube support member 6. For example, the exhaust line 4 may horizontally penetrate the tube support member 6 to come into connection with the tube space 5h.

The pump VP may be connected through the exhaust line 4 to the tube space 5h. The pump VP may outwardly discharge a fluid from the tube space 5h. The pump VP may be a vacuum pump, but the present disclosure are not limited thereto.

The gas supply GS may supply a gas to the internal space 1h and/or the tube space 5h. For example, the gas supply GS may supply a gas through the gas nozzle 2 to the tube space 5h. The gas supply GS may supply a gas for heat transfer. The gas supply GS may supply an inert gas. For example, the gas supply GS may supply a nitrogen (N₂) gas, a carbon dioxide (CO₂) gas, an argon (Ar) gas, and/or a neon (Ne) gas. The gas supply GS may not supply a gas other than an inert gas. For example, while a process is performed, only an inert gas may be supplied to the internal space 1h and/or the tube space 5h.

FIG. 3 illustrates an example enlarged cross-sectional view showing section Y of FIG. 1.

Referring to FIGS. 2 and 3, the heater 7 may be combined with the outer chamber 1. For example, the heater 7 may be rigidly coupled onto an inner lateral surface 1i of the outer chamber 1. The heater 7 may be provided in plural. The plurality of heaters 7 may be disposed spaced apart from each other in the first direction D1. The heater 7 will be further discussed in detail below.

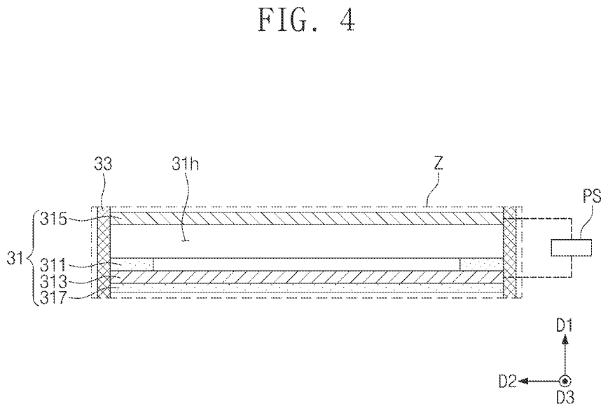

The boat 3 may include a substrate support device 31, an upper body (see 33 of FIG. 4), a lower body 35, and a sealing member 37.

The substrate support device 31 may support a substrate. For example, a substrate may be disposed in the substrate support device 31. The substrate support device 31 may create an electric field. The substrate support device 31 may be provided in plural. The plurality of substrate support device 31 may be arranged in the first direction D1. For example, the plurality of substrate support devices 31 may be stacked vertically. The following will describe a single substrate support device 31. The substrate support device 31 will be further discussed in detail below.

The upper body 33 may extend vertically. The upper body 33 may support the substrate support device 31. The upper body 33 may have a hollow cylindrical shape, but the present disclosure are not limited thereto.

The lower body 35 may support the upper body 33 and/or the substrate support device 31. A boat driving mechanism may cause the lower body 35 to move vertically. Thus, the substrate support device 31 may move vertically.

The sealing member 37 may be positioned on the lower body 35. The sealing member 37 may include, for example, an O-ring. When the boat 3 moves upwardly to be inserted into the process tube 5, the sealing member 37 may contact the tube support member 6. When the boat 3 moves upwardly to be inserted into the process tube 5, the sealing member 37 may hermetically close the tube space 5h.

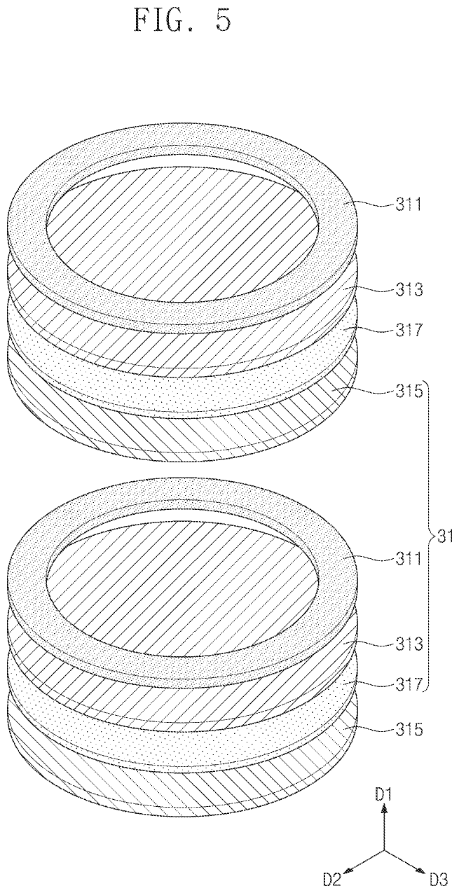

FIG. 4 illustrates an example enlarged cross-sectional view showing section Z of FIG. 3. FIG. 5 illustrates an exploded perspective view showing an example of a substrate processing apparatus.

Referring to FIGS. 4 and 5, the substrate support device 31 may include a support member 311, a lower electrode 313, an upper electrode 315, and a dielectric member 317.

The support member 311 may support a substrate. For example, a substrate may be disposed on a top surface of the support member 311. The support member 311 may be supported by the upper body 33. For example, an edge of the support member 311 may be combined with the upper body 33. The support member 311 may include a dielectric material. For example, the support member 311 may include a ceramic. The present disclosure, however, are not limited thereto. The support member 311 may have a circular shape when viewed in plan. The support member 311 may have, for example, an annular shape. As shown in FIG. 5, the support member 311 may have a hollow circular shape. The present disclosure, however, are not limited thereto, and the support member 311 may have any other suitable shape. For example, the support member 311 may have an annular shape whose one side is opened. Alternatively, the support member 311 may have a disk shape.

The lower electrode 313 may be positioned below the support member 311. The lower electrode 313 may be positioned on a bottom surface of the support member 311. For example, the lower electrode 313 may be positioned below the support member 311 to allow a top surface of the lower electrode 313 to contact the bottom surface of the support member 311. The lower electrode 313 may be supported by the upper body 33. For example, an edge of the lower electrode 313 may be combined with the upper body 33. The lower electrode 313 may have a disk shape. The lower electrode 313 may include a conductive material. For example, the lower electrode 313 may include metal. The lower electrode 313 may be connected to a voltage applying device PS. The voltage applying device PS may apply a DC power and/or a RF power to the lower electrode 313. A detailed description thereof will be further discussed below.

The upper electrode 315 may be disposed upwardly spaced apart from the support member 311. A process space 31h may be defined between the upper electrode 315 and the support member 311. The upper electrode 315 may be supported by the upper body 33. For example, an edge of the upper electrode 315 may be combined with the upper body 33. The upper electrode 315 may have a disk shape. The upper electrode 315 may include a conductive material. For example, the upper electrode 315 may include metal. The upper electrode 315 may be connected to the voltage applying device PS. The voltage applying device PS may apply a DC power and/or a RF power to the upper electrode 315. Thus, an electric field may be created in the process space 31h. A detailed description thereof will be further discussed below.

The dielectric member 317 may be positioned below the lower electrode 313. The dielectric member 317 may include a dielectric material. For example, the dielectric member 317 may include a ceramic. The dielectric member 317 may have a disk shape, but the present disclosure are not limited thereto. The dielectric member 317 may be positioned below the lower electrode 313. For example, the dielectric member 317 may be positioned between the upper electrode 315 of an underlying one of two neighboring substrate support devices 31 and the lower electrode 313 of an overlying one of two neighboring substrate support devices 31. The dielectric member 317 may electrically insulate from each other the upper electrode 315 of an underlying one of two neighboring substrate support devices 31 and the lower electrode 313 of an overlying one of two neighboring substrate support devices 31.

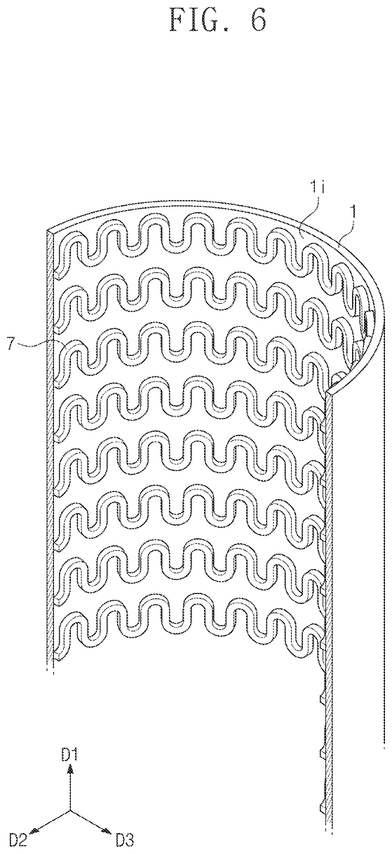

FIG. 6 illustrates a cutoff perspective view showing an example of a substrate processing apparatus.

Referring to FIG. 6, for example, the heater 7 may be combined with the inner lateral surface 1i of the outer chamber 1. The heater 7 may surround the boat (see 3 of FIG. 1). For example, the heater 7 may be disposed to horizontally surround the process space (see 31h of FIG. 4). Thus, the process space 31h may be uniformly heated. The heater 7 may include a plurality of coils. The plurality of coils may be disposed spaced apart from each other in the first direction D1. For example, the plurality of coils may be arrange vertically spaced apart from each other to surround all of the plurality of substrate support devices 31.

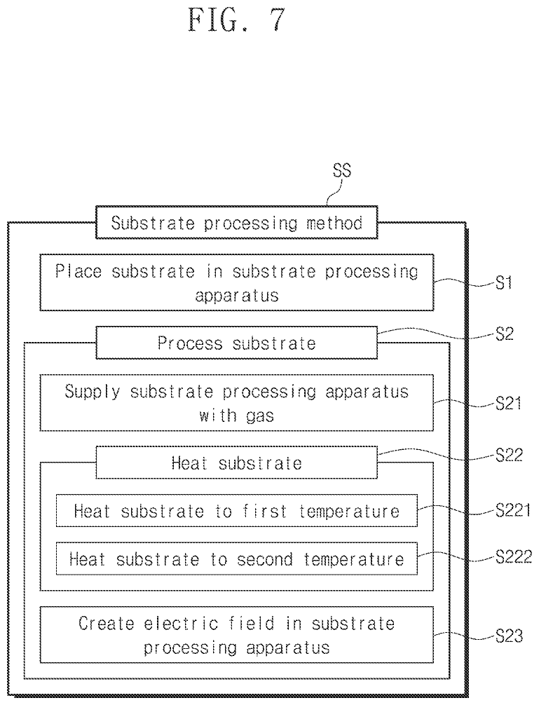

FIG. 7 illustrates a flow chart showing an example of a substrate processing method.

Referring to FIG. 7, a substrate processing method SS may be provided. The substrate processing method SS may be a way of processing a substrate by using the substrate processing apparatus SA discussed with reference to FIGS. 1 to 6. For example, the substrate processing method S may be an annealing process in which a substrate is provided with heat to cause a material on the substrate to diffuse into the substrate. The substrate processing method SS may be a way of performing a metal induced lateral crystallization (MILC) process that diffuses nickel disilicide into a channel in VNAND. The substrate processing method SS may include placing a substrate into a substrate processing apparatus (S1) and processing the substrate (S2).

The substrate processing step S2 may include supplying the substrate processing apparatus with a gas (S21), heating the substrate (S22), and creating an electric field in the substrate processing apparatus (S23).

The substrate heating step S22 may include firstly heating the substrate to a first temperature (S221) and secondly heating the substrate to a second temperature (S222).

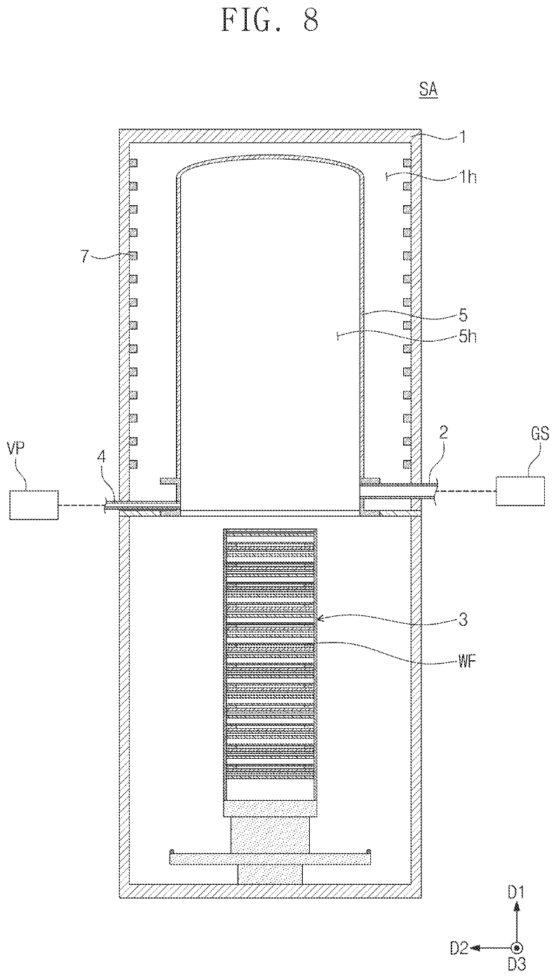

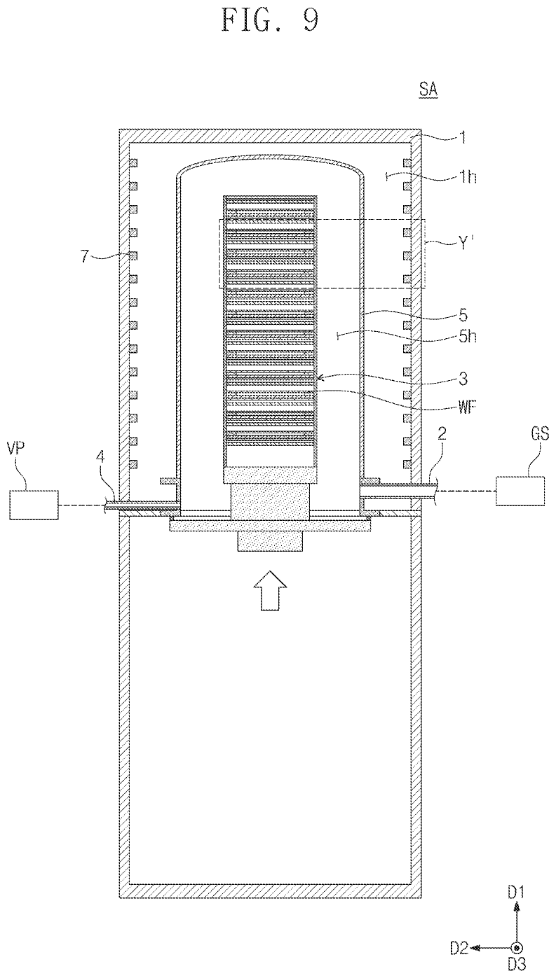

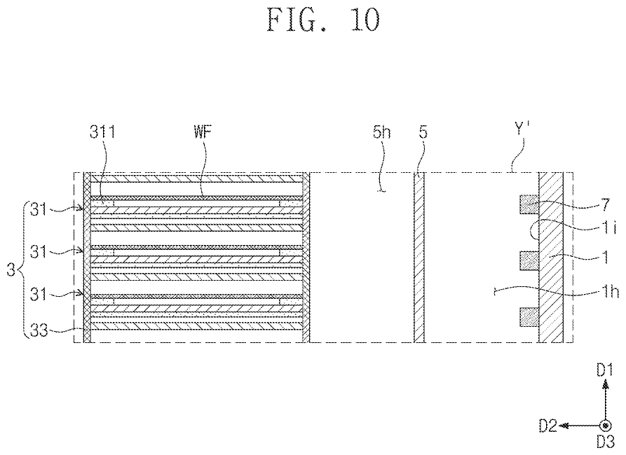

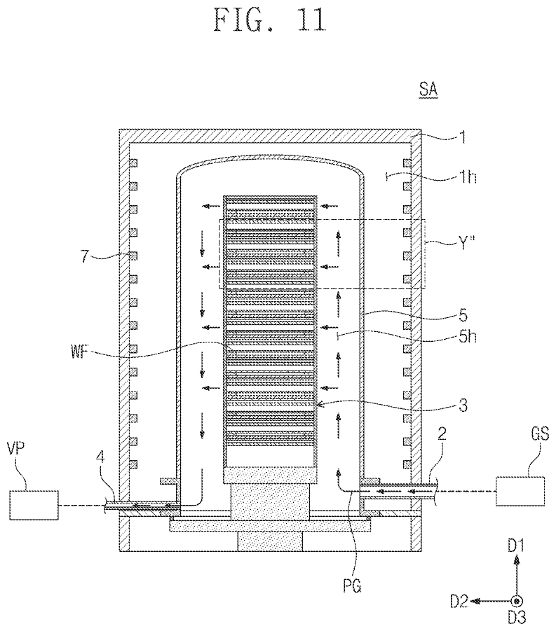

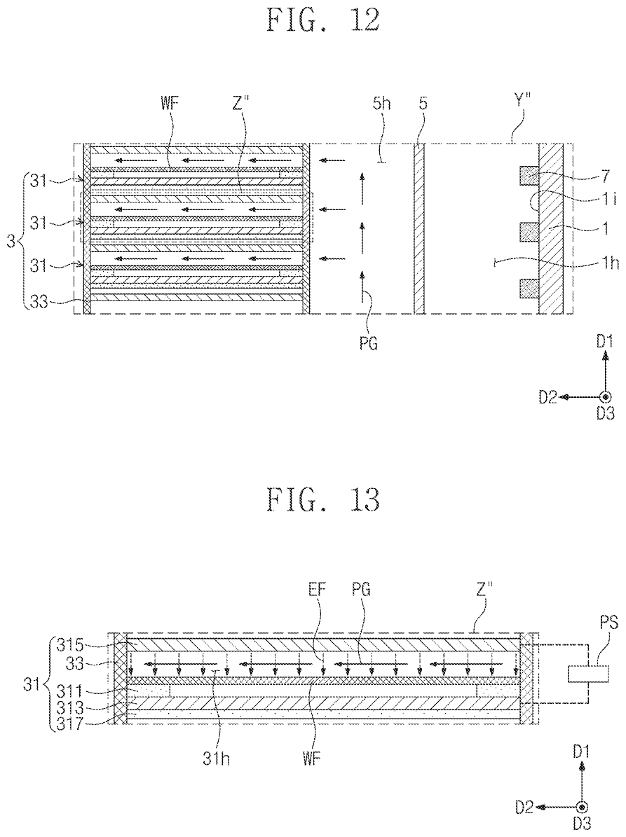

The substrate processing method SS according to the flow chart of FIG. 7 will be discussed below with reference to FIGS. 8 to 13.

FIGS. 8 to 13 illustrate example cross-sectional views showing a substrate processing method according to the flow chart of FIG. 7.

Referring to FIGS. 7, 8, 9, and 10, the substrate placement step S1 may include placing a substrate WF on the substrate support device 31. For example, the substrate WF may be disposed on the support member 311. In this description, the term “substrate” may mean a silicon (Si) wafer, but the present disclosure are not limited thereto. When the substrate support device 31 is provided in plural, a plurality of substrates WF may be correspondingly disposed on the plurality of substrate support devices 31. For example, the plurality of substrates WF may be disposed in the boat 3. The boat 3 may move upwardly in a state where the plurality of substrates WF are disposed in the boat 3. The boat 3 may be disposed in the process tube 5. Thus, the plurality of substrates WF may be located in the tube space 5h.

Referring to FIGS. 7, 11, and 12, the gas supplying step S21 may include allowing the gas supply GS to supply a gas PG through the gas nozzle 2 to the tube space 5h. The gas PG may be a fluid for heat transfer. For example, the gas PG may be a heat transfer gas. The gas PG may include an inert gas. For example, the gas PG may include a nitrogen (N₂) gas, a carbon dioxide (CO₂) gas, an argon (Ar) gas, and/or a neon (Ne) gas. The present disclosure, however, are not limited thereto, and the gas supply GS may supply different kinds of gas. The gas PG may be introduced into the boat 3. For example, the gas PG may be introduced into each of the plurality of substrate support devices 31.

The first heating step S221 may include allowing the heater 7 to heat the substrate WF to a first temperature. When a power is applied to the heater 7, heat may be discharged from the heater 7. The gas PG may transfer the heat discharged from the heater 7 to the substrate WF in the substrate support device 31. Therefore, the substrate WF may be heated. A temperature of the substrate WF may increase to the first temperature. The first temperature may range from about 300° C. to about 500° C., but the present disclosure are not limited thereto. When a temperature of the substrate WF increases to the first temperature, a material on the substrate WF may become instability.

The second heating step S222 may include, after the first heating, allowing the heater 7 to heat the substrate WF to a second temperature. The second temperature may be greater than the first temperature. The second temperature may range from about 700° C. to about 900° C., but the present disclosure are not limited thereto. When a temperature of the substrate WF increases to the second temperature, an instable material formed on the substrate WF may diffuse into the substrate WF.

Referring to FIGS. 7 and 13, the electric field step S23 may include applying a power to the lower electrode 313 and/or the upper electrode 315. For example, the voltage applying device PS may apply a DC power and/or a RF power to the lower electrode 313 and/or the upper electrode 315. Thus, an electric field may be created in the substrate support device 31. For example, an electric field EF may be created in a vertical direction in the process space 31h.

According to a substrate processing apparatus and a substrate processing method using the same in accordance with some implementations of the present disclosure, during an annealing process that heats a substrate, an electric field may be created on the substrate. Thus, an instable material positioned on the substrate may deeply diffuse into the substrate. Accordingly, the material may diffuse to an end of a channel having a large aspect ratio.

According to a substrate processing apparatus and a substrate processing method using the same in accordance with some implementations of the present disclosure, a substrate may be uniformly heated by a heater that surrounds a process space. Therefore, a uniform process may be performed.

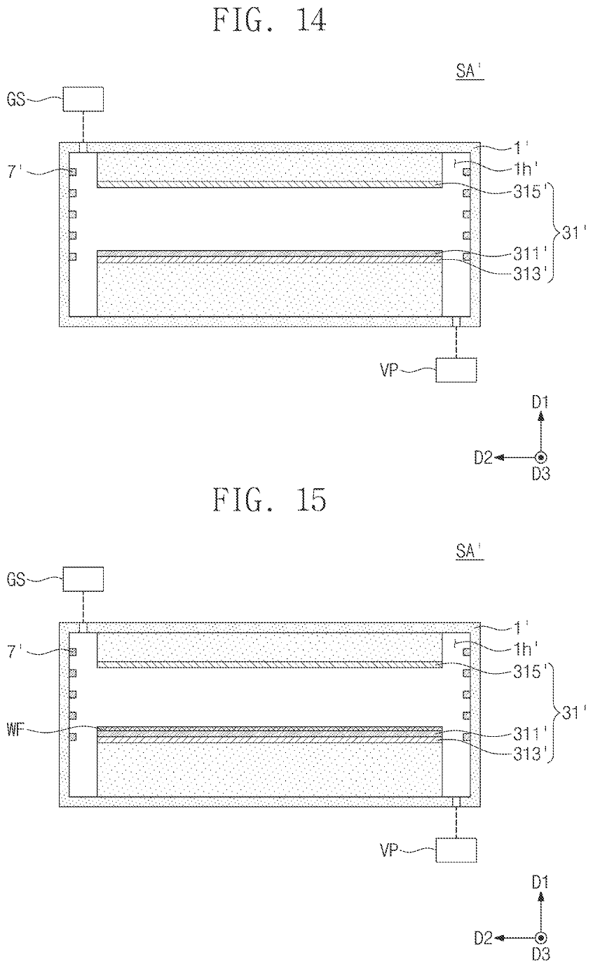

FIG. 14 illustrates a cross-sectional view showing another example of a substrate processing apparatus. FIG. 15 illustrates a cross-sectional view showing a use state of an example of a substrate processing apparatus.

The following will omit a description substantially the same as or similar to that with reference to FIGS. 1 to 13.

Referring to FIGS. 14 and 15, a substrate processing apparatus SA′ may be provided. The substrate processing apparatus SA′ may perform a process on a substrate. The substrate processing apparatus SA′ may heat a substrate. For example, the substrate processing apparatus SA′ may be configured such that a substrate is heated to force a material present on a surface of the substrate to diffuse into the substrate. In this sense, an annealing process may be performed in the substrate processing apparatus SA′. The substrate processing apparatus SA′ may include a process chamber 1′, a substrate support device 31′, a heater 7′, a pump VP, and a gas supply GS.

The process chamber 1′ may provide a process space 1h′. The process chamber 1′ may have a cylindrical shape, but the present disclosure are not limited thereto.

The substrate support device 31′ may be positioned in the process chamber 1′. The substrate support device 31′ may include a support member 311′, a lower electrode 313′, and an upper electrode 315′.

The support member 311′ may support a substrate WF. For example, the substrate WF may be disposed on a top surface of the support member 311′. The support member 311′ may include a dielectric material. For example, the support member 311′ may include a ceramic. The present disclosure, however, are not limited thereto. The support member 311′ may have a circular shape when viewed in plan. For example, the support member 311′ may have a disk shape.

The lower electrode 313′ may be positioned below the support member 311′. The lower electrode 313′ may be positioned on a bottom surface of the support member 311′. For example, the lower electrode 313′ may be positioned below the support member 311′ to allow a top surface of the lower electrode 313′ to contact the bottom surface of the support member 311′. The lower electrode 313′ may have a disk shape. The lower electrodes 313′ may include a conductive material. For example, the lower electrode 313′ may include metal. The lower electrode 313′ may be connected to a voltage applying device. The voltage applying device may apply a DC power and/or a RF power to the lower electrode 313′.

The upper electrode 315′ may be disposed upwardly spaced apart from the support member 311′. The process space 1h′ may be defined between the upper electrode 315′ and the support member 311′. A vertical distance between a bottom surface of the upper electrode 315′ and a top surface of the support member 311′ may range from about 20 mm to about 400 mm. The upper electrode 315 may have a disk shape. The upper electrode 315′ may include a conductive material. For example, the upper electrode 315′ may include metal. The upper electrode 315′ may be connected to the voltage applying device. The voltage applying device may apply a DC power and/or a RF power to the upper electrode 315′. Thus, an electric field may be created in the process space 1h′.

The heater 7′ may horizontally surround the process space 1h′ between the support member 311′ and the upper electrode 315′. The heater 7′ may be combined with, for example, an inner lateral surface of the process chamber 1′. The heater 7′ may include a plurality of coils that are arranged vertically spaced apart from each other.

The vacuum pump VP may be connected to the process space 1h′. The pump VP may outwardly discharge a fluid from the process space 1h′. The pump VP may be a vacuum pump, but the present disclosure are not limited thereto.

The gas supply GS may supply the process space 1h′ with a gas. The gas supply GS may supply a gas for heat transfer. The gas supply GS may supply an inert gas. For example, the gas supply GS may supply a nitrogen (N₂) gas, a carbon dioxide (CO₂) gas, an argon (Ar) gas, and/or a neon (Ne) gas. The gas supply GS may not supply a gas other than an inert gas. For example, while a process is performed, only an inert gas may be supplied to the process space 1h′.

According to a substrate processing apparatus and a substrate processing method using the same in accordance with some implementations of the present disclosure, substrates may be heated one by one to perform an annealing process on the substrate. The substrate may be uniformly heated by using a plurality of coil-type heaters that horizontally surround a process space. Therefore, a uniform annealing process may be performed on the substrate.

According to a substrate processing apparatus and a substrate processing method using the same of the present disclosure, it may be possible to apply a vertical directional electric field.

According to a substrate processing apparatus and a substrate processing method using the same of the present disclosure, it may be possible to uniformly heat a substrate.

According to a substrate processing apparatus and a substrate processing method using the same of the present disclosure, it may be possible to increase a yield.

Effects of the present disclosure are not limited to the mentioned above, other effects which have not been mentioned above will be clearly understood to those skilled in the art from the following description.

While this specification contains many specific implementation details, these should not be construed as limitations on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Although the present disclosure have been described in connection with some implementations of the present disclosure illustrated in the accompanying drawings, it will be understood to those skilled in the art that various changes and modifications may be made without departing from the technical spirit and essential feature of the present disclosure. It therefore will be understood that the implementations described above are just illustrative but not limitative in all aspects.

What is claimed is:

1. A substrate processing apparatus, comprising:
an outer chamber that provides an internal space;
a process tube in the outer chamber;
a heater between the outer chamber and the process tube; and
a boat inserted into the process tube,
wherein the boat includes a plurality of substrate support devices that are vertically stacked,
wherein each substrate support device of the plurality of substrate support devices includes:
a support member that supports a substrate;
a lower electrode below the support member; and
an upper electrode above the support member and spaced apart from the support member.

2. The apparatus of claim 1, wherein the heater is combined with an inner lateral surface of the outer chamber.

3. The apparatus of claim 1, wherein the heater includes a plurality of coils that are arranged vertically and spaced apart from each other.

4. The apparatus of claim 1, comprising a gas nozzle that is configured to provide the internal space with gas.

5. The apparatus of claim 4, wherein the gas nozzle is in the process tube and configured to supply the gas upwards in a tube space provided in the process tube.

6. The apparatus of claim 1, wherein each electrode of the lower electrode and the upper electrode has a disk shape.

7. The apparatus of claim 1, wherein a voltage applying device is connected with at least one electrode of the lower electrode or the upper electrode.

8. The apparatus of claim 1, wherein each substrate support device of the plurality of substrate support devices includes a dielectric member, and
wherein the dielectric member electrically insulates from the upper electrode of an underlying substrate support device of two neighboring substrate support devices and the lower electrode of an overlying substrate support device of two neighboring substrate support devices.

9. A substrate processing apparatus, comprising:
a process chamber;
a support member in the process chamber, the support member supporting a substrate;
a lower electrode below the support member;
an upper electrode above the support member and spaced apart from the support member; and
a heater in the process chamber,
wherein the heater is disposed to horizontally surround a process space, the process space being between the support member and the upper electrode.

10. The apparatus of claim 9, wherein the heater is combined with an inner lateral surface of the process chamber to horizontally surround the process space.

11. The apparatus of claim 10, wherein the heater includes a plurality of coils that are arranged vertically and spaced apart from each other.

12. The apparatus of claim 9, wherein a vertical distance between a top surface of the support member and a bottom surface of the upper electrode is in a range of about 20 mm to about 400 mm.

13. A substrate processing method, comprising:
placing a substrate in a substrate processing apparatus; and
processing the substrate disposed in the substrate processing apparatus,
wherein the substrate processing apparatus includes:
a support member that supports the substrate;
a lower electrode below the support member;
an upper electrode above the support member and spaced apart from the support member; and
a heater that horizontally surrounds a space between the support member and the upper electrode,
wherein processing the substrate includes:
using the heater to heat the substrate on the support member; and
applying a power to at least one electrode of the lower electrode or the upper electrode.

14. The method of claim 13, wherein heating the substrate includes:
heating the substrate to a first temperature; and
after heating the substrate to the first temperature, heating the substrate to a second temperature,
wherein the second temperature is greater than the first temperature.

15. The method of claim 14, wherein
the first temperature ranges from about 300° C. to about 500° C., and
the second temperature ranges from about 700° C. to about 900° C.

16. The method of claim 13, wherein applying the power to the at least one electrode of the lower electrode or the upper electrode includes applying a DC power or a RF power to the at least one electrode.

17. The method of claim 13, wherein the heater includes a plurality of coils that are arranged vertically and spaced apart from each other.

18. The method of claim 17, wherein
the support member, the lower electrode, and the upper electrode provide a substrate support device,
the substrate processing apparatus includes a plurality of substrate support devices including the substrate support device,
the plurality of substrate support devices are vertically stacked, and
wherein placing the substrate in the substrate processing apparatus includes placing a plurality of substrates on the plurality of substrate support devices, respectively.

19. The method of claim 18, wherein the plurality of coils are vertically spaced apart from each other and surround the plurality of substrate support devices.

20. The method of claim 13, comprising supply gas to a space between the support member and the upper electrode,
wherein heating the substrate includes using the gas to transfer heat to the substrate, the heat being discharged from the heater.
